(19) United States
(12) Patent Application Publication
(10) Pub. No.: US 2013/0276886 A1
(43) Pub. Date: Oct. 24, 2013

(54) POLYMER SOLAR CELLS AND FUNCTIONALIZED CONJUGATED POLYMERS

(71) Applicant: THE GOVERNORS OF THE UNIVERSITY OF ALBERTA, Edmonton (CA)

(72) Inventors: Brian J. Worfolk, Edmonton (CA); Weiwei Li, Edmonton (CA); Kenneth Harris, Edmonton (CA); Jillian Buriak, Edmonton (CA)

(73) Assignee: The Governors of the University of Alberta, Edmonton (CA)

(21) Appl. No.: 13/865,710

(22) Filed: Apr. 18, 2013

Related U.S. Application Data
(60) Provisional application No. 61/635,055, filed on Apr. 18, 2012.

(51) Int. Cl. H01L 51/00; H01L 51/42

(52) U.S. Cl. CPC H01L 51/0043; H01L 51/42
USPC 136/263; 524/547; 524/173

(57) ABSTRACT

A functionalized conjugated polymer comprising alternating copolymer donor and acceptor units in which at least one of the donor and acceptor units comprises a linking group and a functional group attached to the linking group. The linking group may comprise an alkyl group. The functional group may comprise one or more carboxyl, halogen (such as fluorine and chlorine), hydroxyl, carbonate, imino, cyano, nitro, amine, and amide functional groups. More than one functional group may be present for each linking group. Not every copolymer unit need have a linked functional group. The linking group may be attached to either or both of the donor and acceptor units. The functional group may terminate the linking group.

### CROSS-REFERENCE TO RELATED APPLICATIONS

This application claims the benefit under 35 USC 119(e) of U.S. provisional application Ser. No. 61/635,055 filed Apr. 18, 2012, which is herein incorporated by reference in its entirety.

### BACKGROUND

Solar energy has attracted much attention to satisfy the ever-increasing demand for energy in our society. Although inorganic solar cells have high power conversion efficiency in utilizing solar energy, their disadvantages include high production cost, long energy payback times, highly energy intensive fabrication and brittleness, and these properties restrict application in the marketplace. Organic solar cells (OSCs), as third generation photovoltaic technology, are a potential replacement which can overcome these disadvantages. As such, OSCs have been intensely studied in the past two decades.

The device structure of organic solar cells often consists of an anode such as indium tin oxide (ITO) and a reflective cathode such as Al. The photoactive layer is commonly an electron donor/electron acceptor pair structured with a complex phase separated bulk heterojunction (BHJ) arrangement, and interfacial layers between both electrodes and photoactive layer assist in charge transport and extraction. Poly(3,4-ethylenedioxythiophene): poly(styrenesulfonate) (PEDOT:PSS) is the most commonly used hole transport layer (HTL) between the photoactive layer and anode. PEDOT:PSS is highly acidic, hydrophilic and has been shown to migrate through all layers in the OSC, which influences the life time and power conversion efficiency of the solar cells. The acidity of PEDOT:PSS has also been shown to contribute to etching of indium from the indium tin oxide electrode, leading to reduced performance over time. Replacement of PEDOT:PSS with functionalized conjugated polymers in the hole transport layer can possibly mitigate these problems.

Additional issues that have been observed include difficulty engineering the energy levels at the HTL/photoactive layer interface, “vertical phase separation” (i.e., the formation of detrimental concentration gradients in the photoactive layer) brought about by non-ideal surface energy in the HTL, and insufficient hole mobility in the HTL. Matching the energetic interface between the anode/HTL and the photoactive layer is required to enable efficient extraction of holes from the photoactive layer to the anode. This requires the selection of appropriate combinations of materials in the photoactive layer and HTL, and often requires additional post-treatments such as annealing. Pairs of materials (HTL/donor) with compatible energy levels must be identified.

Vertical phase separation describes the accumulation of BHJ components (i.e., donor or acceptor) near one of the electrodes (i.e., anode or cathode). Accumulation of donor near the anode may actually be advantageous, but accumulation of acceptor near the anode is almost certainly detrimental. This is, however, fairly common as the surface energy of typical anodic HTLs (such as PEDOT:PSS ˜70 mJ/m²) leads to an increase in acceptor (n-type) accumulation at the HTL/BHJ photoactive layer interface. Ideal BHJ morphology has a higher content of donor (p-type) material at this interface to facilitate the efficient transport of holes to the anode. HTL materials which reduce the surface energy at this interface are preferred and can eliminate additional processing steps (i.e., annealing).

Numerous interfacial modifiers are known including the ubiquitous PEDOT:PSS manufactured by Hereaus, Sigma-Aldrich and others. Researchers have also developed other inorganic materials such as NiOₓ, WOₓ and IrOₓ, and many others, which are commonly applied by thermal evaporation under high vacuum.

PEDOT:PSS has been commonly used in organic solar cells as a hole transport layer to help hole carrier transport from the photoactive layer to the anode. However, PEDOT:PSS is highly acidic and attacks the underlying indium tin oxide (ITO) electrode, and excess NaPSS has been shown to migrate throughout the layers of OSCs, which significantly reduces the lifetime of the solar cells. Researchers also developed other inorganic materials such as NiOₓ, WOₓ and IrOₓ, but the high price and complicated fabrication procedures of these materials restrict their full industrial application and will reduce the mechanical flexibility of OSCs. PEDOT:PSS also commonly induces accumulation of [6,6]-phenyl-C₆₁-butyric acid methyl ester (PCBM) near the anode side of the device, which is a detrimental situation. Additional processing steps (such as thermal or solvent annealing) are then required to correct this. Therefore, developing new materials and concepts for hole transport layers is critical for widespread application of organic solar cells.

### SUMMARY

There is disclosed in an embodiment a functionalized conjugated polymer comprising alternating copolymer donor and acceptor units in which at least one of the donor and acceptor units comprises a linking group and a functional group attached to the linking group. The linking group may comprise an alkyl group. The functional group may comprise one or more carboxyl, halogen (such as fluorine and chlorine), hydroxyl, carbonate, imino, cyano, nitro, amine, and amide functional groups. More than one functional group may be present for each linking group. Not every copolymer unit need have a linked functional group. The linking group may be attached to either or both of the donor and acceptor units. The functional group may terminate the linking group. There is also disclosed an organic solar cell, comprising an anode and a cathode, a polymer photoactive layer between the anode and cathode, a hole transport layer between the photoactive layer and the anode; and the hole transport layer comprising a polymer with a conjugated backbone, a linking group and a functional termination.

### BRIEF DESCRIPTION OF THE FIGURES

Embodiments will now be described with reference to the figures, in which like reference characters denote like elements, by way of example, and in which:

FIG. 1A is Poly[3-(5-carboxypentyl)thiophene-2,5-diyl] (P3CPenT), FIG. 1B is Poly[2-methoxy-5-carboxypentyloxy-1,4-phenylenevinylene] (MECP-PPV), FIG. 1C is Poly[2,7-(9,9-dicarboxylheptyl-fluorene)-alt-5,5-(4.7-di-2-thienyl-2,1,3-benzothiadiazole] (PCFTB), FIG. 1D is Poly[9,9-(2-ethyl-carboxyhexyloxy)-dioctyl-thieno[3,4-c]pyrrole-4,6-dione] (PCBDTTPD), FIG. 1E is Poly[2-(5-(5,6-bis(carboxyheptyloxy)-4-(thiophen-2-yl)benzo[c][1,2,5]thiadiazol-7-yl)thiophen-2-yl)-9-octyl-9H-carbazole] (C-HXS-1).

FIG. 2 is a photovoltaic device structure showing glass substrate, transparent anode for example ITO, reflective cathode for example Al, LiF layer (optional buffer layer, may use other buffer layers or omit), P3HT:PCBM photo-active layer or equivalent polymer photoactive layer, hole transport layer.

FIG. 3A shows the chemical structure of poly[3-(5-carboxypentyl) thiophene-2,5-diyl] (P3CPenT) used to self-assemble nanowires for use as the hole transport layer in plastic solar cells. FIG. 3B shows the device architecture of plastic solar cells consisting of: ITO/P3CPenT/P3HT:PCBM/LiF/Al.

FIG. 4A shows energy levels of the electronic materials used in this study. The energy levels of P3CPenT, P3HT and PCBM were measured by electrochemical cyclic voltammetry. FIG. 4B shows UPS spectra used to calculate the work functions of bare ITO, ITO modified by P3CPenT (12 nm), and PEDOT:PSS (30 nm) from UPS measurement.

### DETAILED DESCRIPTION

Immaterial modifications may be made to the embodiments described here without departing from what is covered by the claims.

We have invented several conjugated polymeric derivatives with carboxylic acid and other units to replace PEDOT:PSS in the hole transport layer for organic solar cells. Exemplary polymers have a conjugated backbone, a linking group, and a functional termination. The set of backbones may be any suitable polymer useful for photovoltaics. The linking group may be alkyl chains (for example 1-20 atoms in length, branched or unbranched, saturated or unsaturated). The most important termination would be carboxylic acid, but other polar groups may be included.

In one embodiment, there is disclosed an organic solar cell, comprising an anode and a cathode; a polymer photoactive layer between the anode and cathode; a hole transport layer between the photoactive layer and the anode; and the hole transport layer comprising a polymer with a conjugated backbone, a linking group and a functional termination. The linking group may comprise an alkyl chain. The functional termination may comprise one or more of a carboxyl, halogen, hydroxyl, carbonate, imino, cyano, nitro, amine, and amide functional group. The function of the hole transport layer is to efficiently transfer holes from the photoactive layer to the anode. For an HTL to be effective, holes must be transferred more effectively with the HTL in place than they would be without the HTL (i.e., directly from active layer to anode). Usually, it is the energy levels that primarily dictate the choice of a particular HTL/donor pair: a useful HTL material reduces energy barriers for charge extraction by providing an energy level accessible by holes that is greater than the highest occupied molecular orbital (HOMO) of the donor and less than the work function of the anode. There are also other auxiliary functions like smoothing out the anode, inducing more of the donor than the acceptor to accumulate at the anode, and having a large conductivity for holes. There is also a solubility consideration that is purely practical: if the HTL and photoactive layers are soluble in the same solutions, then when the photoactive layer is cast, the HTL is likely to be damaged. Therefore, it is beneficial if an HTL and photoactive layer pair have orthogonal solubilities.

We also disclose and claim a functionalized conjugated polymer comprising alternating copolymer donor and acceptor units in which at least one of the donor and acceptor units comprises a linking group and a functional group attached to the linking group. In one embodiment, the linking group comprises an alkyl group. In various embodiments, the functional group may comprise one or more carboxyl, halogen (such as fluorine and chlorine), hydroxyl, carbonate, imino, cyano, nitro, amine, and amide functional groups. More than one functional group may be present for each linking group. Not every copolymer unit need have a linked functional group. The linking group may be attached to either or both of the donor and acceptor units. In an embodiment, the functional group may terminate the linking group.

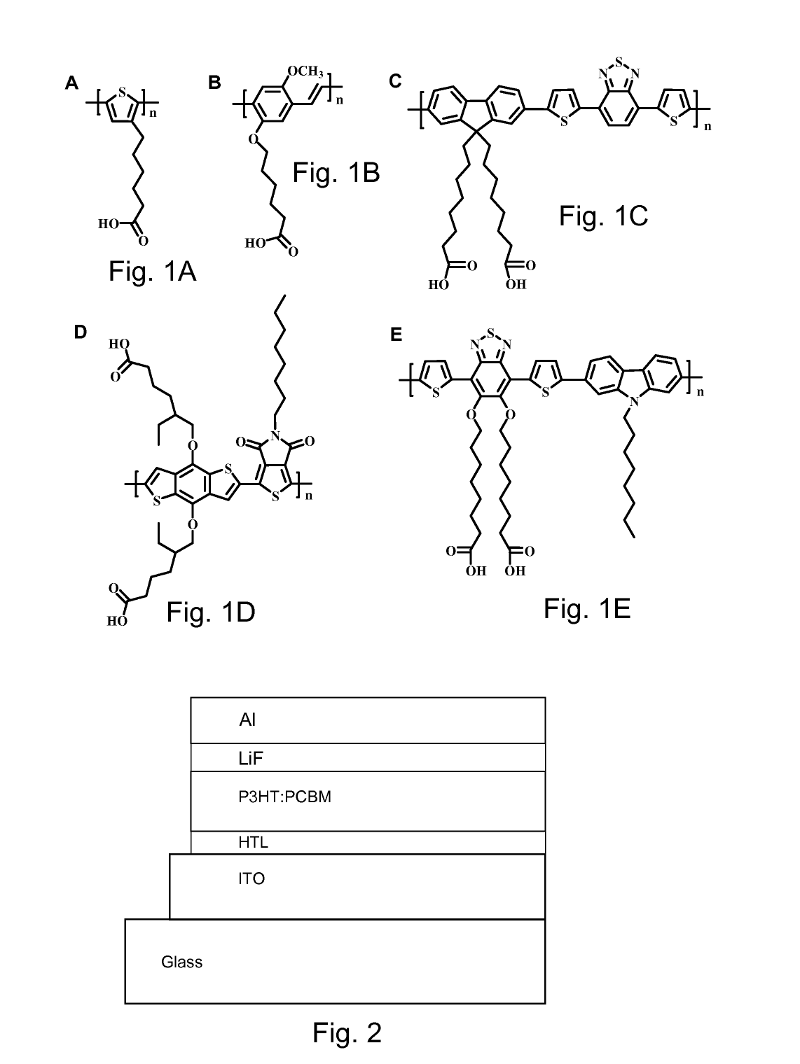

The solar cells based on these derivatives improve power conversion efficiencies and lifetimes over cells formed with PEDOT:PSS as a hole transport layer. The concept is relatively general, as many conjugated electron donor materials in the literature include long alkyl chains to increase solubility in organic solvents. Replacing the alkyl chain in any of these materials with a chain terminated by carboxyl or other functional groups, creates a new set of materials. These new materials have different solubilities (generally less soluble in the traditional photoactive layer solvents chloroform, chlorobenzene and dichlorobenzene, and enhanced solubility in pyridine, dimethyl sulfoxide (DMSO), alcohols, etc). This property has been observed to allow films of the new materials to survive the addition of photoactive layers above them. Each of these materials may be used in the fabrication of solar cells as ITO interfacial modifiers. A selection of the specific materials invented includes those materials shown in FIGS. 1A-1E (Note: the material shown in FIG. 1A has been reported and synthesized by Rieke Metals Inc.):

With the addition of the COOH end group, the surface energy of thin films formed with these materials is reduced as compared to the alkyl-only chain. This property helps prevent PCBM from accumulating nearby and reduces the detrimental effect of vertical phase separation.

In addition, the end of the alkyl chain of semiconducting polymers can be functionalized with halogens (such as fluorine and chlorine), hydroxyl, carbonate, imino, cyano, nitro, amine, and amide functional groups or any which change the solubility making the polymers insoluble (or poorly soluble) in common organic solvents typically used in processing of the photoactive layer including: chloroform, chlorobenzene and ortho-dichlorobenzene. As previously mentioned, this will allow for subsequent processing after deposition of the invented hole transport materials. See FIG. 2 for an example of a possible device architecture.

We have demonstrated the self-assembly of nanowire (NW) networks in solution for material in FIG. 1A. This simply involves dissolving the material in DMSO, heating above 90° C. and cooling to room temperature. Upon cooling, the polymer self-assembles into NWs in solution, which are stable in solution for more than 2 years. Pre-forming NWs in solution reduces additional annealing in an inert atmosphere and vapour phase annealing, which are normally required to form NWs in the solid-state. It is expected that the other functionalized polythiophenes in FIGS. 1B-1E will also behave this way. These pre-formed NWs have application in many organic electronic devices including organic photovoltaic devices (OPVs), organic light emitting diodes (OLEDs), organic field-effect transistors (OFETs), organic sensors and smart textiles.

For example, we have demonstrated the use of Poly[3-(5-carboxypentyl)thiophene-2,5-diyl] (P3CPenT) NWs (“A”) as an HTL in OPVs. We have shown this material to have several advantages over conventional PEDOT:PSS: i) better energetic matching with the donor poly(3-hexylthiophene) (P3HT) material, ii) the semi-crystalline solution cast NWs facilitate charge extraction and iii) improve the morphology of the subsequent BHJ photoactive layer by reducing the surface energy (vide supra).

In summary, we have invented a simple method for self-assembling carboxylated semiconducting polymers in solution which can be used to match electronic properties of subsequent layers, improve morphology of subsequent layers and improve charge extraction and device performance.

A photovoltaic device structure showing glass substrate, transparent anode for example ITO, reflective cathode for example Al, LiF layer (optional buffer layer, may use other buffer layers or omit), P3HT:PCBM photo-active layer or equivalent polymer photoactive layer, hole transport layer is disclosed here. The HTL represents any of the carboxylate derivates or the additional ones identified. The HTL is preferably spin cast (spray-coated or roll-to-roll printed) on an ITO coated glass substrate or other suitable substrate. This layer is incompatible to the subsequent processing step whereby the photoactive layer: P3HT:PCBM is spin cast on top from ortho-dichlorobenzene. The photovoltaic cell layers should be in this order: anode/HTL/donor/acceptor/electron transport layer (ETL)/cathode. The donor and acceptor are usually mixed together in the bulk heterojunction arrangements, so that can usually be treated like a single combined layer. One of the anode or cathode must be transparent. The structural substrate (glass, PET, quartz) can be on either side. In inverted mode, the anode is on top, and it might be, for example, Ag rather than ITO, and light comes in on the cathode side. Or, the top electrode could be a transparent anode, but then the electrode on the glass side is a reflective metal, for example Mo. In some instances, an HTL may function as an ETL, if the donor/acceptor pair has appropriate energy levels. A multilayer device with the disclosed cell configuration may also be used, for example in a “tandem solar cell”, two or more solar cells are “stacked” on one another. The photoactive layers for each of the stacked cells are chosen so they absorb light in different ranges. In this case, a layer structure like this is used: anode/HTL1/donor1/acceptor1/ETL1/recombinationlayer/HTL2/donor2/acceptor2/ETL2/cathode, and as discussed, the proposed materials could be HTL1 or HTL2, or ETL1 and ETL2 depending on energy levels. The ETL can be omitted with a potential loss of performance.

Conjugated polymer derivatives with COOH endgroups mentioned above are a new concept in OSCs. They have appeared before in the photoactive layer, but not as interfacial modifiers. In the most advantageous arrangement, a conjugated polymer is used as an electron donor in the photoactive layer, and its COOH-modified counterpart is used as the interfacial modifier. In this case, the backbone structures are similar, which ensures appropriate energy levels for charge transport between the two materials. Moreover, these COOH-modified derivatives automatically have desirable solubility properties: high solubility in some polar solvent such as pyridine and DMSO, while they have poor solubility in chloroform, chlorobenzene and dichlorobenzene. Thus, the COOH-functionalized polymers are amenable to casting of additional overlayers from solvents commonly used for the photoactive layer (such as chloroform, chlorobenzene and dichlorobenzene). The COOH-termination (or other groups) may also reduce the surface energy of cast films, preventing the detrimental effect of vertical phase separation and the accumulation of PCBM near the anode. Also, the highly-crystalline NW morphology of the HTL observed for P3CPenT may be advantageous for charge transport through the HTL, and this benefit may be observed for other functionalized polythiophenes invented, including those listed in FIGS. 1A-1E. Finally, these polymers should have lower acidity than that of PEDOT:PSS, which should restrict ITO etching and improve the lifetime of solar cells. The pKa of PSS is 1 while often carboxylic acids have a pKa of ˜5.

Carboxy-functionalized polythiophenes have been used in dye sensitized solar cells. Here the purpose is to anchor the carboxylated polythiophene to the TiO₂ oxide surface, allowing the formation of a stable film⁵⁻⁴³. In this case, the carboxy-functionalized polythiophene acts as the absorber or sensitizer, whereas in our invention the material is used as an interfacial buffer layer.

In addition, there is no mention in the literature of halogen (such as fluorine and chlorine), hydroxyl, carbonate, imino, cyano, nitro, amine, and amide functional groups for semiconducting polymers. Each of these endgroups should be able to impart different solubilities without enormously affecting the electronic states of the conjugated backbone.

This is the first report demonstrating the fast self-assembly of semiconducting NWs in solution. Jenekhe et al. have extensively studied the self-assembly of polythiophene-based NWs through the interdigitation of alkyl chains and lamellar packing in homopolymers and block copolymers. Typically poor solvents or storage in dark, vibrationless environments for ˜72 hours are required for self-assembly to occur¹³⁻²². Our system adds a carboxyl group to the alkyl chain to aid in the self-assembly of NWs which can be achieved in seconds in DMSO.

Based on the disclosed results and the properties of like materials, we can soundly predict that most of the soluble conjugated polymers currently used for organic photovoltaics (or other organic electronics applications) should work in the proposed solar cell that have alkyl chains extending away from a conjugated backbone. Most commonly, one alkyl chain appears for every repeat unit in the polymer, but sometimes there are two or more chains per repeat unit, or sometimes the alkyl chains appear after every second or third repeat unit. Theoretically, variants of every one of these polymers could be synthesized. The variants would have all (or only some) of the alkyl chains replaced with carboxyalkyl chains. This modification is almost certain to affect the solubility of the molecules, such that the carboxyalkyl-terminated version will tend to be soluble in more polar solvents than the alkyl-terminated version.

Preparation method depends on material. Each COOH-terminated polymer will have its own preferred solvent(s), and these may be experimentally determined or confirmed for every material. In all cases, the COOH-terminated polymer should tend to be soluble in more polar solvent than the alkyl terminated version. Regarding deposition methods, for the P3CPenT material, we developed an “absorption from solution method” that also appeared to adequately form working solar cells. The COOH-terminated materials may also be deposited by printing (spray-coating, screen printing, ink-jet, gravure, etc.), drop casting, or any other solution casting technique with sufficient thickness resolution.

Alternate electrodes: graphene, carbon nanotubes, metal nanowires (Ag, Au, Cu, etc.), alternate transparent conducting oxides (fluorine-doped tine oxide (FTO), Al doped ZnO (AZO), TiOx, etc.), organic conducting polymers such as PEDOT:PSS. It is also conceivable that an “inverted mode” process could be used. In that case, the electrode could be a higher work function metal such as Ag. If the new polymers are used in applications outside photovoltaics, then high work function metals such as gold would be very likely as electrodes. The choice of electrode doesn't necessarily depend on HTL material, although the fabrication process may need to be adjusted if different electrodes are to be used.

Alternate active layers: To simplify things, we have tended to think of each carboxyalkyl-terminated polymer being used as a hole transport layer while paired with its alkyl-terminated version in the active layer. This isn't necessarily the only arrangement; any other conjugated donor could potentially be substituted. The PCBM acceptor could also be substituted, with one very likely possibility being the indene C60 bisadduct (ICBA).

Substrates: Glass is the most likely, but quartz or other transparent materials could also be used. More relevantly, transparent plastic films such as polyethylene terephthalate or polyethylene naphthalate could be used to form flexible solar cells.

In our process, 8 nm was determined to be the optimum P3CPenT film thickness with P3HT:PCBM used in the active layer. With a different active layer, the optimum P3CPenT thickness may be slightly different. For different carboxyalkyl-terminated polymers, we would re-optimize the process to determine the best possible thickness, so thickness is likely to depend on material. Based on our experience with P3CPenT, it appears that the COOH— polymer is preferably as thin as possible while still forming a continuous and complete coating on the electrode.

We apply P3CPenT NWs from DMSO solution as an HTL beneath a P3HT:PCBM photoactive layer: the pendant carboxyalkyl group renders the P3CPenT NWs insoluble in common photoactive layer solvents such as chloroform, chlorobenzene (CB) and dichlorobenzene (DCB), allowing conventional BHJ active layers to be applied over P3CPenT films using standard spin casting procedures. Due to their similar conjugated backbones, the P3CPenT derivative has energy levels similar to the donor, and thus charge transfer across the P3CPenT/P3HT interface is energetically favourable. Transmission electron microscopy (TEM) is used to characterize the impact of different HTLs (no HTL, PEDOT:PSS or P3CPenT NWs) on the morphology of the BHJ and the associated influence on photovoltaic device performance.

All chemicals were purchased from commercial suppliers and used without further purification. P3CPenT and P3HT were purchased from Rieke Metals, Inc. PCBM, PEDOT:PSS and Al (99.99%) were purchased from American Dye Source (ADS61BFA), Heraeus (Clevios P VP AI 4083) and Kurt J. Lesker respectively. ITO coated glass substrates (8-12Ω/□) were purchased from Delta Technologies Ltd., and all solvents and LiF were purchased from Sigma Aldrich.

The self-assembly of P3CPenT NWs was performed by dissolving P3CPenT (1 mg/mL to 15 mg/mL) in DMSO and stirring for 12 hours at 90° C. in an inert environment, followed by cooling to room temperature. Films were fabricated by directly spin coating the NW solution on freshly cleaned ITO at different rotation speeds in air to achieve different thicknesses. All samples were subsequently annealed in air for 10 min at 90° C. To form P3CPenT films by adsorption from solution, ITO was first cleaned then immersed in a 4 mg/mL P3CPenT solution in DMSO for 24 hours. The modified substrates were then thoroughly rinsed with DMSO, ultrasonicated in DMSO for 30 min, spin dried at 3000 rpm and finally heated to 90° C. for 10 min. The thickness of P3CPenT film was determined by AFM.

Plastic solar cells (PSCs) were fabricated with the device configuration ITO/HTL/P3HT:PCBM/LiF/Al, in which the HTL was either PEDOT:PSS or P3CPenT. ITO-coated glass substrates were cleaned by successive 10 min ultrasonications in methylene chloride, Millipore water (18 MΩ·cm) and 2-propanol followed by a 10 min air plasma treatment at ˜0.1 mTorr (Harrick Plasma, PDC 32G, 18W). Self-assembled P3CPenT NW films were formed as described above. Specifically, P3CPenT NW films with 8 nm thickness were prepared by spin-coating 5 mg/mL P3CPenT solution in DMSO at 3000 rpm for 3 min. For reference cells in which PEDOT:PSS acted as the HTL, aqueous PEDOT:PSS solution was passed through a 0.2 μm cellulose acetate filter directly onto the cleaned ITO substrates and spin-cast at 3500 rpm for 1 min to form a layer ˜30 nm thick. To form PEDOT:PSS films of different thicknesses, the spin coating speed and solution concentration were varied. All PEDOT:PSS samples were annealed in air for 10 min at 125° C.

For all PSC photoactive layers, individual 23 mg/mL solutions of P3HT and PCBM in dichlorobenzene (DCB) were prepared in an inert argon atmosphere and stirred at ˜60° C. for several hours. Following stirring, the individual solutions were combined 1:1 by weight, stirred, and spin-cast at 600 rpm for 1 min in air. The samples were then covered and dried over the course of 15-20 minutes. The thickness of the P3HT:PCBM active layer was 200±10 nm. Devices were completed by thermal evaporation of 0.6 nm of LiF and 80 nm of aluminum, forming a device area of 0.20 cm².

Photovoltaic performance was measured in air under AM 1.5 G simulated solar irradiation with a xenon solar simulator (Oriel 91191 1000 W). The testing irradiance was calibrated against a certified Si reference cell fitted with a KG-5 filter (model PVM624, PV Measurements, Inc.). Device J-V characteristics were measured using a Keithley 2400 source meter. Devices for stability testing were stored inside a glove box under a nitrogen atmosphere between testing periods and were tested at ambient conditions in air.

The energy levels of P3CPenT, P3HT and PCBM were investigated using cyclic voltammetry (Princeton Applied Research Potentiostat model 2273) with a standard three-electrode electrochemical cell. A glassy carbon working electrode, a Pt wire counter electrode, and a Ag/AgNO3 reference electrode were used, and the electrolyte was 0.1 M tetrabutylammonium hexafluorophosphate (nBu4NPF6) in acetonitrile solution. The reference potential was calibrated to a ferrocene redox couple, and a scan rate of 100 mV/s was employed. X-ray photoelectron spectroscopy (XPS, Kratos Analytical, Axis-Ultra) was performed using monochromatic Al Kα X-ray irradiation at a photon energy of 1486.6 eV on P3CPenT films cast by both spin coating and absorption from solution. The XPS instrument was calibrated using the C(1 s) signal (BE=284.9 eV).

Work functions of the modified ITO surfaces were determined by ultraviolet photoelectron spectroscopy (UPS) using the He I line (hν=21.2 eV). The power for UPS was 3 kV×10 mA (30 W), and samples were biased at −10 V during all measurements to observe the secondary electron edge. The average and standard deviation of three spots on the same sample are reported. Contact angle measurements were conducted using a Rame-Hart NRL C.A. contact angle Goniometer system (No. 100-00) using water and n-hexadecane under ambient conditions (22° C.). A Nanoscope IV (Digital Instruments/Veeco) instrument, operated in tapping mode with commercially-available Si cantilevers (Asylum Research, 300 kHz), was used for atomic force microscopy. To determine the thickness of organic films, the same instrument was operated in contact mode to excavate a section of the organic material, and then the trench depth was measured in tapping mode.

For TEM, P3CPenT solution in DMSO (0.1 mg/mL) was dropped onto carbon-coated TEM grids and imaged with a JEOL JEM 2100 TEM at a 120 kV acceleration voltage. For cross sectional TEM imaging, Si substrates were first cleaned and treated with air plasma, the HTL layers were applied as described above, and P3HT:PCBM active layers were then spin-cast above. Cross sectional TEM samples were prepared using a Hitachi NB 5000 FIB/SEM dual beam system. Two protection layers (30 nm sputtered carbon, and 1 μm FIB-assisted sputtered tungsten) were deposited first to avoid Ga ion beam damage to the films during subsequent FIB processing. TEM lamellae sections were rough milled and transferred onto to a TEM grid using a 40 kV primary Ga+ beam and subsequently thinned/polished using a 10 kV primary Ga+ beam to a thickness of less than 100 nm. Bright-field TEM images were acquired on a JEOL 2200FS TEM/STEM at 200 kV accelerating voltage.

X-ray diffraction (XRD) was performed using a Bruker D8 Discover instrument with a Cu Kα beam (40 kV, 40 mA; λ=1.541784 Å) and operated at a glancing angle, ω=2 o. For these XRD measurements, P3CPenT NW samples were spin-casted from DMSO solution on clean Si wafers, and peaks in the XRD pattern were identified in terms of the Bragg angle, 2θ, and calibrated to a LaB6 NIST standard (SRM-660b). The integration time for all samples was 1 hour. Optical absorption or transmission spectra were measured on an Agilent 8453 UV-Vis Spectrophotometer.

The self-assembly of polythiophene-based NWs through the interdigitation of alkyl chains and lamellar packing in homopolymers and block copolymers has been extensively studied by Jenekhe et al.²³⁻²⁸ Typically poor solvents or storage in dark, vibrationless environments for ˜72 h are required for self-assembly to occur.²⁹⁻³² Using a similar motif, we added P3CPenT to DMSO at 90° C., resulting in an orange solution. This was stirred for 12 h, and subsequently cooled to room temperature, yielding a purple coloured solution within ˜30 s. Optical absorbance of P3CPenT solutions in pyridine and DMSO (after heating and cooling to room temperature) show observed wavelengths of peak absorbance (λₘₐₓ) were 449 nm and 480 nm in pyridine and DMSO, respectively. The bathochromic shift observed in DMSO is indicative of increased effective conjugation length, often the result of increased molecular ordering (higher degree of coplanar alignment in the thiophene backbone).²⁷ Additional prominent features in the DMSO solution absorbance spectrum are two shoulders at 547 nm and 594 nm. Typically these peaks are characteristic of additional electronic transitions based on π-stacking of polymer chains, as the result of increased molecular ordering.^{27,29,33} The absence of these shoulders for P3CPenT in pyridine indicates dissolution, and a lack of self-assembled molecular ordering, in contrast to the semicrystalline self-assembled morphology in DMSO (as evidenced through increased coplanar ordering of the thiophene backbone and π-stacking of polymer chains, vide supra). UV-vis absorbance spectra for solid-state P3CPenT thin films cast from DMSO and pyridine solutions were also performed, and show, and in both cases, solid-state spectra are red-shifted compared to the corresponding solution spectra. Spectra for the films cast from DMSO are also red-shifted compared to pyridine-cast counterparts, with the λₘₐₓ shifting from 505 nm to 552 nm, and peaks characteristic of π-stacking are evident only in the DMSO-cast films at 552 nm and 599 nm. These results indicate increased π-stacking in DMSO-cast films.²⁷ Both DMSO- and pyridine-cast films also appear to have non-zero absorption above 650 nm, possibly indicative of doping and the associated generation of charge carriers.

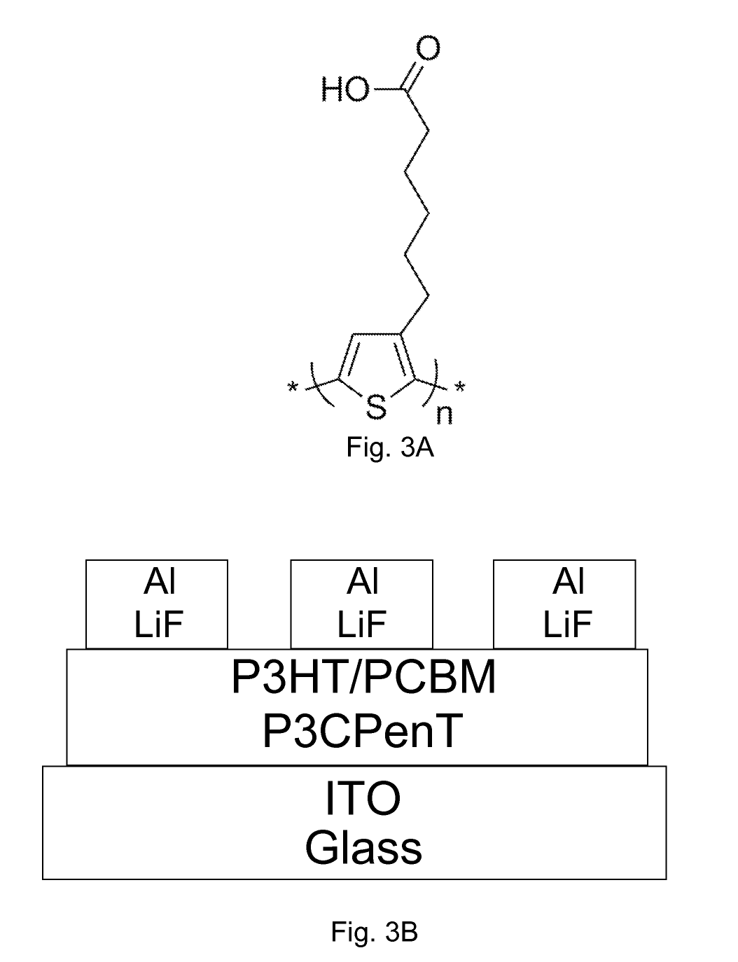

As shown in FIG. 3A, P3CPenT bears carboxyl groups on pentyl side chains attached to the polythiophene backbone. In our previous work, hydrogen bonds originating from the carboxyl groups were identified by Fourier transform infrared spectroscopy (FTIR) measurements of pyridine:chlorobenzene (1:6, v/v) cast films.²² In the present work, the crystalline structures of P3CPenT films spin cast from DMSO and pyridine solutions were studied by XRD. The spectrum for the film cast from DMSO shows peaks at 2θ=5.4° and 10.8°, which are attributed to carboxyalkyl chain stacking along the (100) and (200) directions, respectively. The measured (100) d-spacing was 16.4 Å, which is similar to the (100) d-spacing of 16.8 Å previously reported for pyridine:chlorobenzene (1:6, v/v) cast films of P3CPenT.²² The XRD peaks indicate crystalline lamellar packing of P3CPenT units, and applying the Scherrer equation to the (100) peak allows us to determine an average spherical crystallite size of 11.9 nm.³⁴ Similar P3CPenT films cast from pyridine had XRD peaks in the same positions, but these peaks were much weaker and showed significantly reduced crystal sizes (5.7 nm) compared to DMSO-cast films. This observation is consistent with the UV-vis absorbance data and supports the claim that DMSO-cast P3CPenT films are more crystalline than pyridine-cast counterparts. McCullough et al. reported on the self-assembly of poly[3-(2-carboxyethyl)thiophene-2,5-diyl] (P3CET), which has an ethyl linker instead of the pentyl chain in P3CPenT.66 P3CET was shown to self-assemble via hydrophobic interactions that were stabilized by hydrogen bonding, as characterized by the presence of a carboxylic acid dimer stretch in the infrared spectrum.³⁵ As such, we hypothesize that hydrogen bonding formation of dimers, aids in the molecular structuring of P3CPenT NW films.

The morphology of P3CPenT NW films cast from a low concentration (0.1 mg/mL) DMSO solution was characterized by TEM and atomic force microscopy (AFM). TEM analysis reveals the presence of P3CPenT NWs with an average width of 8.0±1.0 nm. It is difficult to characterize the length of the NWs because they form an interconnected network, and endpoints cannot be identified. As seen by AFM, the average width is 9-10 nm, which is slightly larger than the TEM measurements and is likely the result of tip convolution effects.³⁶ As can be seen from AFM, the P3CPenT NWs appear to be made up of smaller interconnected segments that are about 70±30 nm in length, calculated from an average of 50 measurements. Both TEM and AFM, when coupled with the XRD and UV-Vis results, confirm the presence of semicrystalline P3CPenT NWs.

To characterize the chemical and electronic properties of the interfaces, films of P3CPenT were analysed by XPS and compared to untreated ITO substrates. The XPS spectra of the S(2p) region show distinctive sulphur peaks only in samples modified with P3CPenT. This signal originates in the polythiophene backbone and indicates the presence of the P3CPenT layer. For unmodified ITO surfaces, the binding energy peak for Sn(3d) is present at 495.0 eV, and binding energy peaks for In(3d) are found at 444.6 eV and 452.2 eV. When modified with P3CPenT, the binding energy peaks shift to higher energies of 497.4 eV for Sn(3d), and 445.8 eV and 453.4 eV for In(3d), indicating surface modification.³⁷ ITO was modified by P3CPenT with spin coating method with S(2p), Sn(3d), and In(3d). P3CPenT from solution method and spin coating method afford the same thickness of 6 nm measured by AFM.

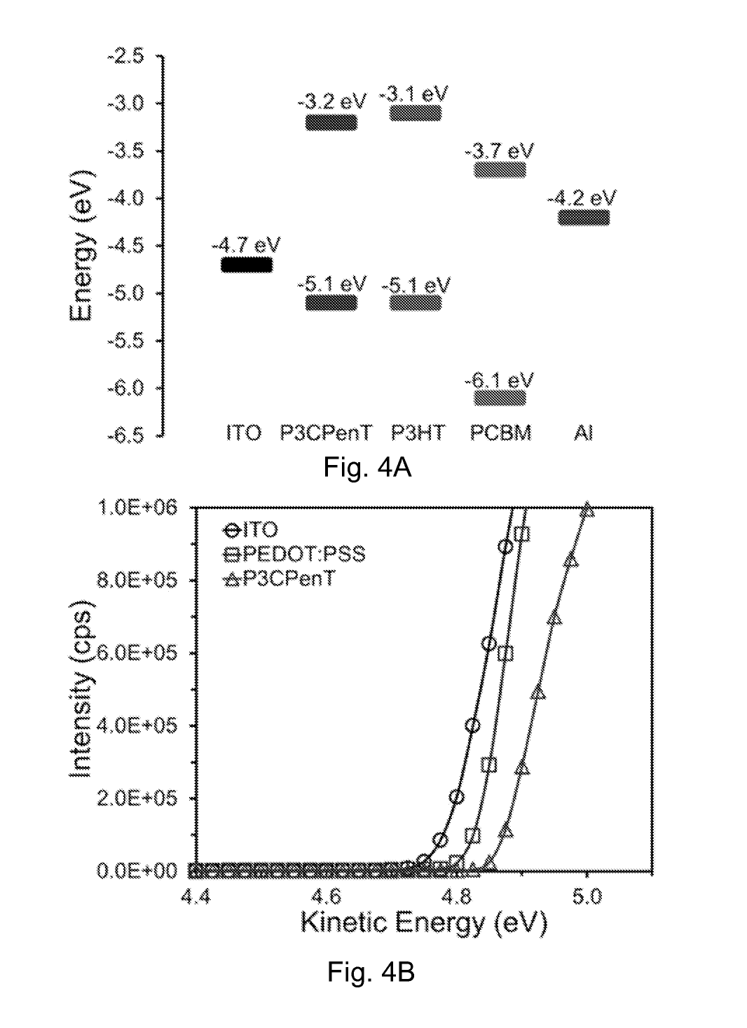

FIG. 4A illustrates the energy levels of the electronic materials in this work. The values for P3CPenT, P3HT and PCBM were measured by electrochemical cyclic voltammetry,²² and the work functions of ITO and Al are from literature.³⁸ The HOMO energy of P3CPenT is −5.1 eV, which as predicted, is the same as the HOMO level of P3HT. The similarity between these two values should lower the energy barrier for charge transfer and allow efficient hole transport between P3HT and P3CPenT. Ultraviolet photoelectron spectroscopy (UPS) was utilized to determine the surface work functions of unmodified ITO, P3CPenT-modified ITO, and PEDOT:PSS-modified ITO. As shown in FIG. 4B, when ITO was modified by PEDOT:PSS or P3CPenT, the secondary electron cutoff slightly shifts to greater kinetic energies, indicating an increased surface work function. The measured values of the work functions are 4.78±0.01 eV, 4.82±0.01 eV and 4.99±0.03 eV for unmodified ITO, PEDOT:PSS-modified ITO and P3CPenT-modified ITO, respectively. Moreover, we found that the work function did not vary strongly with P3CPenT thickness in our measurements of 8, 12, and 36 nm films.

Contact angles of ITO, PEDOT:PSS-modified ITO, and P3CPenT-modified ITO with water and n-hexadecane were determined on freshly cleaned surfaces, and the results are summarized in Table 2, below. Low contact angles were observed for unmodified ITO both with water and with n-hexadecane (9° and 9°),³⁷ and roughly similar values were recorded for ITO modified by PEDOT:PSS (4° in water and 10° in n-hexadecane). The contact angles for P3CPenT-modified ITO were significantly different: 47° in water and 3° in n-hexadecane, indicating a more hydrophobic surface despite the prevalence of hydrophilic hydrogen bonds. Accordingly, the surface energies were calculated based on the literature³⁹ and are shown in Tables 1 and 2, below. The surface energies were similar for unmodified and PEDOT:PSS-modified ITO (72 mJ/m² and 73 mJ/m2), whereas the surface energy of P3CPenT NW-modified ITO was lower at 55 mJ/m².

The method to calculate the surface energy relies on the following set of

$$\begin{matrix}1 + cos θ = 2 \sqrt{γ sd} ( \frac{\sqrt{γ ld}}{γ lv} ) + 2 √ γ sh ( \frac{\sqrt{γ lh}}{γ lv} ) \\ and & [ 1 ] \\ {γ}_{s} = {γ}_{s}^{d} + {γ}_{s}^{h} & [ 2 ]\end{matrix}$$

In these equations the indices h and d refer the hydrogen bonding and dispersion force components, while s and l denote solid or liquid. γₛ refers to the surface energy of the solid, γ/ν is the surface energy of the liquid, and θ is the contact angle of the liquid with the solid surface. The surface energy parameters were found tabulated in the literature⁵⁰, and the relevant values are listed in Table 1.

TABLE 1
Summarized contact angles of Si substrates modified by
PEDOT:PSS or P3CPenT.

| | Water | n-Hexadecane | Surface |
|---|---|---|---|
| | contact angle | contact | energy |
| | (°) | angle (°) | (mJ/m²) |
| Unmodified Si | 9 | 9 | 72 |
| Si modified by | 4 | 10 | 73 |
| PEDOT:PSS | | | |
| Si modified by | 47 | 4 | 54 |
| P3CPenT | | | |

To determine γₛ, we substitute the measured contact angle and known parameters γₗ^{d}, γₗ^{h} and γₗ^{v} and into equation [1] for both H2O and n-hexadecane as solvents. This forms a system of two equations in two unknowns that may be solved to calculate γₛ^{d} and γₛ^{h}. Equation [2] is then invoked to determine γₛ.

Deconvolution of the surface energy into dispersion surface energy, γₛ^{d}, and hydrogen bond surface energy, γₛ^{h}, components indicates that the γₛ^{h} is responsible for the reduced surface energy of P3CPenT modified interfaces as seen in Table 2, below. The surface energy of substrates has considerable influence over concentration gradients in BHJ photoactive layers and hence influences the PSC device performance.^{3,40} Because P3HT has a lower surface energy than PCBM, when hydrophilic PEDOT:PSS is used as the HTL, P3HT tends to accumulate near the air/BHJ interface while PCBM accumulates closer to the hydrophilic PEDOT:PSS HTLs.³ This surface-induced concentration of PCBM near the anode is detrimental to forward mode PSC operation as a more uniform distribution of P3HT and PCBM (or, possibly even more advantageous, a greater P3HT content near the anode) would be preferred to reduce recombination.^{3,40} As has been suggested previously,³ gradient formation occurs during the solvent evaporation step following spin-coating, and decreasing the surface energy of the anode tends to reduce the magnitude of concentration gradients. For example, Baik et al. introduced a thin layer of P3HT with low surface energy between PEDOT:PSS and the P3HT:PCBM active layer, encouraging PCBM to accumulate at the top of the active layer.⁴¹

TABLE 2
Contact angles and surface energies of ITO surfaces modified
with PEDOT:PSS or P3CPenT.

| | | n-Hexa- | | Hydrogen | |
|---|---|---|---|---|---|
| | Water | decane | Dispersion | bonding | |
| | contact | contact | surface | surface | Surface |
| | angle | angle | energy, | energy, | energy, |
| | (°) | (°) | γₛ^{d} (mJ/m²) | γₛ^{h} (mJ/m²) | γₛ (mJ/m²) |
| Unmodified | 9 | 9 | 27 | 45 | 72 |
| ITO | | | | | |
| ITO | 4 | 10 | 27 | 46 | 73 |
| modified by | | | | | |
| PEDOT:PSS | | | | | |
| ITO | 47 | 3 | 28 | 27 | 55 |
| modified by | | | | | |
| P3CPenT | | | | | |

TABLE 3
Summary of PV characteristics of the BHJ OPVs including averages of four devices
and standard deviations (in parentheses) of the short circuit current density (J_{SC}),
open circuit voltage (V_{OC}), fill factor (FF) and power conversion efficiency (PCE)
with different thickness of P3CPenT as HTL.

| Thickness of | | | | | | |
|---|---|---|---|---|---|---|
| P3CPenT | J_{SC} | | | | R_{S} | R_{SH} |
| (nm) | (mA/cm²) | V_{OC} (V) | FF | PCE (%) | (Ω cm²) | (kΩ cm²) |
| 0 | 9.2 (0.2) | 0.52 (0.01) | 0.51 (0.01) | 2.4 (0.1) | 6.0 (0.1) | 0.34 (0.09) |
| 5 | 9.3 (0.1) | 0.559 (0.004) | 0.610 (0.007) | 3.2 (0.1) | 6.8 (0.3) | 1.7 (0.1) |
| 8 | 9.3 (0.2) | 0.555 (0.002) | 0.666 (0.006) | 3.4 (0.1) | 6.5 (0.2) | 1.81 (0.04) |
| 12 | 9.1 (0.1) | 0.553 (0.002) | 0.665 (0.006) | 3.4 (0.1) | 6.5 (0.1) | 1.88 (0.05) |
| 36 | 8.5 (0.1) | 0.548 (0.002) | 0.670 (0.007) | 3.2 (0.1) | 6.2 (0.2) | 1.86 (0.07) |
| 120 | 7.5 (0.1) | 0.549 (0.004) | 0.67 (0.01) | 2.8 (0.1) | 6.1 (0.1) | 1.92 (0.06) |

The influence of the HTL surface energy over the morphology of P3HT:PCBM BHJ films was studied by cross sectional TEM imaging. Samples consisting of P3HT:PCBM spin-cast on various HTLs were prepared on an unmodified Si substrate, a PEDOT:PSS modified Si substrate and a P3CPenT modified Si substrate, and cross-sectional TEM images were collected for each. Control samples consisting only of carbon prepared under the same conditions are uniformly bright, indicating that thickness variations in the TEM samples are not large and do not significantly contribute to variations in the intensity profile. Therefore, based on electron density, bright regions indicate increased P3HT content while darker regions correspond to areas of greater PCBM concentration.⁴² Distinct PEDOT:PSS and P3CPenT layers are clearly observed in HTLs prepared on PEDOT:PSS modified Si substrate and P3CPenT modified Si substrate. For the unmodified and PEDOT:PSS-modified substrates, dark regions are obvious near the Si substrates, and brighter regions are prevalent closer to the BHJ/air interface. This gradient indicates that PCBM accumulates near the HTL. Using P3CPenT in place of PEDOT:PSS, we observed a uniform TEM image intensity, indicating a homogeneous distribution of P3HT and PCBM throughout the film. This more uniform distribution of P3HT and PCBM is expected to improve the device performance of solar cells.

The properties P3CPenT as an HTL were investigated using P3HT:PCBM as a photoactive layer in an ITO/HTL/P3HT:PCBM/LiF/Al architecture under AM 1.5 G simulated solar illumination. The influence of P3CPenT thickness over device performance was investigated, and the photovoltaic parameters are summarized in Table 3, above. The spin-cast P3CPenT thickness ranged from 5 nm to 120 nm as determined by AFM. It should be noted that these P3CPenT films were cast from higher concentration DMSO solution than the low concentration (0.1 mg/mL) DMSO solution, and thus considerably thicker, more interconnected films were formed. Devices including P3CPenT as an HTL performed considerably better than devices without a distinct interfacial layer: open circuit voltage (VOC), fill factor (FF), and power conversion efficiency (PCE) increased. When the thickness of P3CPenT increased from 5 nm to 8 nm, short-circuit current density (JSC) and VOC remained roughly constant around ˜9 mA/cm² and 0.55 V, respectively, while the FF increased slightly from 0.61 to 0.67. The increased FF may originate from a reduced leakage current (i.e., increased shunt resistance, RSH), increasing surface area for charge collection through the interfacial layer on ITO, or reduced concentration of PCBM near the anode.⁴ As the thickness of P3CPenT further increased from 8 nm to 120 nm, VOC, series resistance (RS), RSH and FF remained relatively constant. The stable RS potentially indicates that the P3CPenT conductivity is relatively large, and that device resistance may be dominated by layers other than the HTL. The JSC, however, gradually decreased from 9.3 mA/cm2 to 7.5 mA/cm² as the P3CPenT thickness increased from 8 to 120 nm. This trend of decreasing JSC with increasing P3CPenT thickness is more pronounced than the corresponding trend observed with PEDOT:PSS as an HTL. The thickness of PEDOT:PSS has less influence over P3HT:PCBM PSC performance, although the PCE decreases slightly (4.6% reduction from 30 nm to 160 nm).⁴³ The decreasing JSC likely originates from light absorption by P3CPenT in the range 400-600 nm, which overlaps with the absorption band of P3HT. Transmission spectra of ITO and ITO modified with different thicknesses of P3CPenT were measured. When the P3CPenT thickness increases from 0 nm (i.e., only ITO) to 120 nm, the minimum transmission located at about 550 nm decreases from 85% (0 nm P3CPenT thickness) to 80% (8 nm) to 46% (120 nm), which reduces absorption of photons within the P3HT:PCBM active layer and consequently reduces the output current density. To determine the effect of P3CPenT crystallinity and the nanowire architecture, control experiments were also performed comparing more crystalline DMSO-cast HTLs to less crystalline pyridine-cast films (vide supra) in P3HT:PCBM PSC devices. In these experiments, DMSO-cast HTLs performed considerably better with superior JSC, FF, RS, and RSH (see Table 5, below). The PCE of DMSO-cast devices were 23% greater than pyridine-cast devices, indicating the importance of crystallinity in the HTL to facilitate efficient charge extraction.

P3HT:PCBM BHJ solar cells with optimized PEDOT:PSS and P3CPenT HTLs were investigated in detail and compared to devices fabricated without HTLs. The resulting current density-voltage (J-V) curves, and the extracted PV parameters are summarized in Table 4 below. The control device operating without a distinct HTL performed poorly, but when P3CPenT (8 nm) or PEDOT:PSS (30 nm) were introduced, the JSC remained constant, while both VOC and FF increased. The increase in VOC and FF may originate from the increased RSH as shown in Table 4, compared with low RSH induced by leakage current in samples without HTLs.⁴⁴ Comparing devices with PEDOT:PSS and P3CPenT HTLs, we found that the JSC and VOC were approximately similar, while the FF improved from 0.61 to 0.67 and the RS decreased from 8.17 Ω·cm² to 6.45 Ω·cm² when PEDOT:PSS was replaced with P3CPenT. We propose that the increased FF may partially originate from the following three factors: (1) the increased work function of P3CPenT NW-modified films, reducing the energy barrier for hole extraction;⁴⁵ (2) elimination of the P3HT:PCBM concentration gradient provides better routes for hole transport, reducing charge recombination at the P3HT/HTL interface for forward solar cells; and (3) improved hole transport through semi-crystalline P3CPenT nanowires.²³ Finally, devices incorporating P3CPenT as an interfacial layer gave an average PCE of 3.4%, outperforming PEDOT:PSS PSCs and indicating that P3CPenT NWs could replace PEDOT:PSS in P3HT:PCBM solar cells.

Device stability was also investigated. For both PEDOT:PSS and P3CPenT-based devices, the VOC was roughly constant, while the JSC and FF decreased over time. For PEDOT:PSS, the PCE maintained 57% of its original value after 78 days, and for P3CPenT, the PCE maintained 64% of its original value after the same time period. Although the difference is neither large nor clear, the greater value for P3CPenT devices may be attributable to reduced ITO etching because Na+PSS− has been shown to slowly etch ITO⁴⁶ and/or corrode the Al electrode after diffusion through the active layer^{.1,2} The poor lifetime for these cells may, however, also be dominated by degradation of the low work function cathode and reactions with the active layer materials in the forward-mode solar cells.^{47,48}

A carboxylated poly(3-hexylthiophene) derivative, P3CPenT, was used as a hole transport layer between a transparent ITO electrode and P3HT:PCBM photoactive layer. P3CPenT has several desirable properties as an HTL, including solubility only in certain polar solvents (that do not match the solvents for solubilizing P3HT:PCBM) and energy levels similar to P3HT. Moreover, P3CPenT films formed a nanowire network when cast from DMSO solution, and ITO surfaces modified with P3CPenT were found to be lower in surface energy than those modified with PEDOT:PSS. This property reduces the tendency of P3HT:PCBM photoactive layers cast above P3CPenT to form concentration gradients with an increased PCBM concentration near the hole-collecting anode. Consequently, photovoltaic devices with P3CPenT HTLs showed improved FF (0.67) and PCE, as compared to devices with PEDOT:PSS HTLs. These properties collectively point toward a generalized strategy to exploit conjugated donors in combination with their carboxylated derivatives: the pairs may have orthogonal solubilities yet matching electronics, and lead to improved BHJ morphologies without additional heating and processing steps.

TABLE 4
Average photovoltaic parameters of four devices fabricated with only ITO,
PEDOT:PSS (30 nm), and P3CPenT (8 nm) as HTL. Standard deviations are included in
parentheses.

| | J_{sc} | | | | Rₛ | Rₛₕ | |
|---|---|---|---|---|---|---|---|
| HTL | (mA/cm²) | V_{oc} (V) | FF | PCE (%) | (Ω cm²) | (kΩ cm²) | Best PCE (%) |
| ITO only | 9.2 (0.2) | 0.52 (0.01) | 0.51 (0.01) | 2.4 (0.1) | 6.0 (0.1) | 0.34 (0.09) | 2.5 |
| PEDOT:PSS | 9.2 (0.1) | 0.55 (0.003) | 0.61 (0.01) | 3.1 (0.1) | 8.2 (0.1) | 1.78 (0.03) | 3.4 |
| P3CPenT | 9.3 (0.2) | 0.56 (0.002) | 0.67 (0.01) | 3.4 (0.1) | 6.5 (0.2) | 1.81 (0.04) | 3.7 |

TABLE 5
The average (over nine devices) photovoltaic performance of PSCs made with
P3CPenT HTLs cast from DMSO and pyridine. For DMSO-casting, a 5 mg/ml solution was
spin-cast at I 000 rpm, and for pyridine-casting, a 2.5 mg/mL solution was spin-cast at 3000 rpm,
both for 5 minutes. The resulting P3CPenT films were both measured via ellipsometry to be 11 nm
thick. All HTL spin-casting was done at 90° C., and the samples were annealed subsequently
in air at 90° C. Standard deviations are included in parentheses.

| | J_{sc} | | | | Rₛ | Rₛₕ |
|---|---|---|---|---|---|---|
| Casting Solution | (mA/cm²) | V_{oc} (V) | FF | PCE (%) | (Ω cm²) | (kΩ cm²) |
| DMSO | 7.62 (0.40) | 0.58 (0.004) | 0.60 (0.01) | 2.67 (0.12) | 6.65 (0.67) | 0.71 (0.13) |
| Pyridine | 6.57 (0.34) | 0.57 (0.003) | 0.58 (0.02) | 2.17 (0.09) | 7.76 (0.63) | 0.58 (0.23) |

In the claims, the word “comprising” is used in its inclusive sense and does not exclude other elements being present. The indefinite articles “a” and “an” before a claim feature do not exclude more than one of the feature being present. Each one of the individual features described here may be used in one or more embodiments and is not, by virtue only of being described here, to be construed as essential to all embodiments as defined by the claims.

### LIST OF REFERENCES MENTIONED

1 K. Norrman, N. B. Larsen and F. C. Krebs, Sol. Energy Mater. Sol. Cells, 2006, 90, 2793.
2 K. Norrman, S. A. Gevorgy5 an and F. C. Krebs, ACS Appl. Mater. Interfaces, 2009, 1, 102.
3 Z. Xu, L. M. Chen, G. Yang, C. H. Huang, J. Hou, Y. Wu, G. Li, C. S. Hsu and Y. Yang, Adv. Funct. Mater., 2009, 19, 1227.
4 M. D. Irwin, D. B. Buchholz, A. W. Hains, R. P. H. Chang and T. J. Marks, Proc. Natl. Acad. Sci USA, 2008, 105, 2783.
5 F. Liu, S. Shao, X. Guo, Y. Zhao and Z. Xie, Sol. Energy Mater. Sol. Cells, 2010, 94, 842.
6 G. H. Jung, K. G. Lim, T. W. Lee and J. L. Lee, Sol. Energy Mater. Sol. Cells, 2011, 95, 1146.
7 V. Shrotriya, G. Li, Y. Yao, C. W. Chu and Y. Yang, Appl. Phys. Lett., 2006, 88, 073508.
8 S. Shao, F. Liu, Z. Xie and L. Wang, J. Phys. Chem. C, 2010, 114, 9161.
9 S. W. Tong, C. F. Zhang, C. Y. Jiang, G. Liu, Q. D. Ling, E. T. Kang, D. S. H. Chan and C. Zhu, Chem. Phys. Lett., 2008, 453, 73.
10 A. W. Hains, C. Ramanan, M. D. Irwin, J. Liu, M. R. Wasielewski and T. J. Marks, ACS Appl. Mater. Interfaces, 2010, 2, 175.
11 S. Berny, L. Tortech, M. Veber and D. Fichou, ACS Appl. Mater. Interfaces, 2010, 2, 3059.
12 S. S. Li, K. H. Tu, C. C. Lin, C. W. Chen and M. Chhowalla, ACS Nano, 2010, 4, 3169.
13 H. Y. Wei, J. H. Huang, K. C. Ho and C. W. Chu, ACS Appl. Mater. Interfaces, 2010, 2, 1281.
14 C. W. Liang, W. F. Su and L. Wang, Appl. Phys. Lett., 2009, 95, 133303.
15 G. K. R. Senadeera, K. Nakamura, T. Kitamura, Y. Wada and S. Yanagida, Appl. Phys. Lett., 2003, 83, 5470.
16 J. K. Lee, W. S. Kim, H. J. Lee, W. S. Shin, S. H. Jin, W. K. Lee and M. R. Kim, Polym. Adv. Technol., 2006, 17, 709.
17 K. Shankar, G. K. Mor, H. E. Prakasam, O. K. Varghese and C. A. Grimes, Langmuir 2007, 23, 12445.
18 J. Liu, E. N. Kadnikova, Y. Liu, M. D. McGehee and J. M. J. Frechet, J. Am. Chem. Soc., 2004, 126, 9486.
19 F. C. Krebs, Sol. Energy Mater. Sol. Cells, 2008, 92, 715.
20 C. J. Bhongale and M. Thelakkat, Sol. Energy Mater. Sol. Cells, 2010, 94, 817.
21 M. Thomas, B. J. Worfolk, D. A. Rider, M. T. Taschuk, J. M. Buriak and M. J. Brett, ACS Appl. Mater. Interfaces, 2011, 3, 1887.
22 B. J. Worfolk, D. A. Rider, A. L. Elias, M. Thomas, K. D. Harris and J. M. Buriak, Adv. Funct. Mater., 2011, 21, 1816.
23 H. Xin, F. S. Kim and S. A. Jenekhe, J. Am. Chem. Soc., 2008, 130, 5424.
24 H. Xin, O. G. Reid, G. Ren, S. Kim, D. S. Ginger and S. A. Jenekhe, ACS Nano, 2010, 4, 1861.
25 G. Ren, P. T. Wu and S. A. Jenekhe, ACS Nano, 2011, 5, 376.
26 P. T. Wu, G. Q. Ren, C. Li, R. Mezzenga and S. A. Jenekhe, Macromolecules, 2009, 42, 2317.
27 P. T. Wu, H. Xin, F. S. Kim, G. Ren and S. A. Jenekhe, Macromolecules, 2009, 42, 8817.
28 H. Xin, G. Ren, F. S. Kim and S. A. Jenekhe, Chem. Mater., 2008, 20, 6199.
29 S. Berson, R. D. Bettignies, S. Bailly and S. Guillerez, Adv. Funct. Mater., 2007, 17, 1377.
30 G. Lu, H. Tang, Y. Qu, L. Li and X. Yang, Macromolecules, 2007, 40, 6579.
31 J. A. Merlo and C. D. Frisbie, J. Phys. Chem. B, 2004, 108, 19169.
32 K. J. Ihn, J. Moulton and P. Smith, J. Polym. Sci., Part B: Polym. Phys., 1993, 31, 735.
33 R. Osterbacka, C. P. An, X. M. Jiang and Z. V. Vardeny, Science, 2000, 287, 839.
34 T. Erb, U. Zhokhavets, G. Gobsch, S. Raleva, B. Stuhn, P. Schilinsky, C. Waldauf and C. J. Brabec, Adv. Funct. Mater., 2005, 15, 1193.
35 R. D. McCullough, P. C. Ewbank and R. S. Loewe, J. Am. Chem. Soc., 1997, 119, 633.
36 P. Markiewicz and M. C. Goh, Langmuir, 1994, 10, 5.
37 S. A. Paniagua, P. J. Hotchkiss, S. C. Jones, S. R. Marder, A. Mudalige, F. S. Marrikar, J. E. Pemberton and N. R. Armstrong, J. Phys. Chem. C, 2008, 112, 7809.
38 G. Li, C. W. Chu, V. Shrotriya, J. Huang and Y. Yang, Appl. Phys. Lett., 2006, 88, 253503.
39 D. K. Owens and R. C. Wendt, J. Appl. Polym. Sci., 1969, 13, 1741.
40 A. S. Anselmo, L. Lindgren, J. Rysz, A. Bernasik, A. Budkowski, M. R. Andersson, K. Svensson, J. van Stam and E. Moons, Chem. Mater., 2011, 23, 2295.
41 J. Y. Oh, W. S. Jang, T. I. Lee, J. M. Myoung and H. K. Baik, Appl. Phys. Lett., 2011, 98, 023303.
42 W. Li, Y. Zhou, B. V. Andersson, L. M. Andersson, Y. Thomann, C. Veit, K. Tvingstedt, R. P. Qin, Z. Bo, O. Inganäs, U. Wurfel and F. Zhang, Org. Electron., 2011, 12, 1544.
43 Y. Kim, A. M. Ballantyne, J. Nelson and D. D. C. Bradley, Org. Electron., 2009, 10, 205.
44 H. Xu, L. Yang, H. Tian, S. Yin and F. Zhang, Optoelectron. Lett., 2010, 6, 176.
45 M. S. Kim, B. G. Kim and J. Kim, ACS Appl. Mater. Interfaces, 2009, 1, 1264.
46 C. W. T. Bulle-Lieuwma, W. J. H. van Gennip, J. K. J. van Duren, P. Jonkheijm, R. A. J. Janssen and J. W. Niemantsverdriet, Appl. Surf Sci., 2003, 203, 547.
47 M. Jorgensen, K. Norrman and F. C. Krebs, Sol. Energy Mater. Sol. Cells, 2008, 92, 686.
48 J. Nishinaga, T. Aihara, H. Yamagata and Y. Horikoshi, J. Cryst. Growth, 2005, 278, 633.
49 D. K. Owens, R. C. Wendt, J. Appl. Polym. Sci. 1969, 13, 1741.
50 B. Janczuk. E. Chibowski, J. Coll. Inter. Sci. 1983. 95. 268.

What is claimed is:

1. An organic solar cell, comprising:
an anode and a cathode;
a polymer photoactive layer between the anode and cathode;
a hole transport layer between the photoactive layer and the anode; and
the hole transport layer comprising a polymer with a conjugated backbone, a linking group and a functional termination.

2. The organic solar cell of claim 1 in which the linking group comprises an alkyl chain.

3. The organic solar cell of claim 1 in which the functional termination comprises one or more of a carboxyl, halogen, hydroxyl, carbonate, imino, cyano, nitro, amine, and amide functional group.

4. The organic solar cell of claim 1 in which the hole transport layer and photoactive layer pair have orthogonal solubilities.

5. A functionalized conjugated polymer comprising alternating copolymer donor and acceptor units in which at least one of the donor and acceptor units comprises a linking group and a functional group attached to the linking group.

6. The functionalized conjugated polymer of claim 5 in which the linking group comprises an alkyl group.

7. The functionalized conjugated polymer of claim 5 in which the functional group comprises one or more carboxyl, halogen (such as fluorine and chlorine), hydroxyl, carbonate, imino, cyano, nitro, amine, and amide functional groups.

8. The functionalized conjugated polymer of claim 5 in which more than one functional group is present for each linking group.

9. The functionalized conjugated polymer of claim 5 in which not every copolymer unit has a linked functional group.

10. The functionalized conjugated polymer of claim 5 in which the linking group is attached to either or both of the donor and acceptor units.

11. The functionalized conjugated polymer of claim 5 in which the functional group terminates the linking group.

12. A method for the self-assembly of nanowire networks comprising dissolving a functionalized conjugated polymer in dimethyl sulfoxide, heating above 90° C. and cooling to room temperature.
